(19) United States
(12) Patent Application Publication
(10) Pub. No.: US 2025/0388046 A1
(43) Pub. Date: Dec. 25, 2025

(54) DRIVING WHEEL AND TRANSPORT APPARATUS INCLUDING THE SAME

(71) Applicant: Samsung Display Co., Ltd., Yongin-si (KR)

(72) Inventors: JAE IK BAE, Yongin-si (KR); PILHO LEE, Yongin-si (KR); SANGHYUN MOON, Yongin-si (KR); HEUNGWON LEE, Yongin-si (KR); HEECHANG LEE, Yongin-si (KR); YONGHYEON CHOI, Yongin-si (KR); SUNTAEK HONG, Yongin-si (KR)

(21) Appl. No.: 19/080,672

(22) Filed: Mar. 14, 2025

(30) Foreign Application Priority Data
Jun. 25, 2024 (KR) 10-2024-0083176
Jul. 15, 2024 (KR) 10-2024-0093189

(51) Int. Cl. B60B 19/00; B61C 3/00; H01L 21/677

(52) U.S. Cl. CPC B60B 19/00; B61C 3/00; B60B 2900/513; H01L 21/67724

(57) ABSTRACT

A transport apparatus includes: a body; and a driving wheel that is rotatably connected to the body around a central axis, wherein the driving wheel comprises a wheel housing, the wheel housing comprises a first side positioned opposite to the body along the central axis direction and a second side that faces the body, and at least one cooling passage that penetrates between the first side and the second side is in the wheel housing.

### CROSS-REFERENCE TO RELATED APPLICATION

The present application claims priority to and the benefit of Korean Patent Application No. 10-2024-0093189, filed on Jul. 15, 2024, in the Korean Intellectual Property Office, and Korean Patent Application No. 10-2024-0083176, filed on Jun. 25, 2024, in the Korean Intellectual Property Office, the entire disclosures of each of which are incorporated herein by reference.

### BACKGROUND

### 1. Field

Aspects of some embodiments of the present disclosure relate to a driving wheel and a transport apparatus including the same.

### 2. Description of the Related Art

Production of a display panel, a semiconductor, and the like may be carried out inside a clean room. A transport apparatus may be used in the clean room for transporting logistics. The transport apparatus may transport a display panel and a wafer in the production process. In addition, the transport apparatus may transport items used in the production of a display panel, a semiconductor, and the like.

As the transport apparatus is used, tires may age. In addition, tires may experience partial shrinkage and expansion due to load. Partial shrinkage and expansion cause heat to be generated in the tire. Such a heating phenomenon may accelerate the aging of tires and may increase the amount of particles generated from tires.

The above information disclosed in this Background section is only for enhancement of understanding of the background and therefore the information discussed in this Background section does not necessarily constitute prior art.

### SUMMARY

Aspects of some embodiments of the present disclosure include a driving wheel with effective cooling and a transport apparatus including the same.

A transport apparatus according to some embodiments includes: a body; and a driving wheel that is rotatably connected to the body around a central axis, wherein the driving wheel may include a wheel housing, the wheel housing may include a first side positioned opposite to the body along the central axis direction and a second side that faces the body, and at least one cooling passage that penetrates between the first side and the second side may be in the wheel housing.

According to some embodiments, the cooling passage may be inclined with respect to a direction parallel to the central axis.

According to some embodiments, the cooling passage may be inclined in a rotating direction of the wheel housing while receding from the first side towards the second side.

According to some embodiments, the cooling passage may be provided in plurality and arranged along a circumferential direction centered on the central axis.

According to some embodiments, the first side may include: a fastening portion that is arranged in an inner region in the radial direction centered on the central axis; and a raised portion arranged in an outer region in the radial direction centered on the central axis, and the raised portion may be more protruding than the fastening portion in the opposite direction to the second side.

According to some embodiments, one end of the cooling passage may be positioned in the fastening portion.

According to some embodiments, the driving wheel may further include a heat dissipation module that is connected to the wheel housing and increases a contact area with the air.

According to some embodiments, the heat dissipation module may include: a cooling plate having a ring structure; and at least one auxiliary cooling plate having a ring structure and connected to the cooling plate.

According to some embodiments, at least one communication hole may be on the cooling plate, the communication hole being aligned with one end of the cooling passage.

According to some embodiments, at least one auxiliary communication hole aligned with the communication hole may be in the auxiliary cooling plate.

According to some embodiments, the transport apparatus may further include a connection portion that connects the cooling plate and the auxiliary cooling plate.

According to some embodiments, the communication hole may be provided in plurality, and the connection portion may be in a section between the communication holes.

According to some embodiments, the heat dissipation module may include: a cooling plate having a ring structure and having at least one communication hole aligned with one end of the cooling passage; and a guide portion adjacent to the communication hole and protruding outward from one surface of the cooling plate.

According to some embodiments, the guide portion may be adjacent to the communication hole on one side of the rotating direction of the wheel housing when reversing based on the circumferential direction.

According to some embodiments, the heat dissipation module may further include an auxiliary cooling plate having a ring structure and connected to the guide portion.

A driving wheel according to some embodiments includes a wheel housing, wherein the wheel housing may include a first side and a second side respectively at opposite ends along a central axis direction, and a cooling passage that penetrates the first side and the second side may be in the wheel housing.

According to some embodiments, the cooling passage may be inclined with respect to a direction parallel to the central axis.

According to some embodiments, the driving wheel may further include a heat dissipation module connected to the first side of the wheel housing and increasing the contact area with the air.

According to some embodiments, the heat dissipation module may include: a cooling plate having a ring structure and having at least one communication hole aligned with one end of the cooling passage; and at least one auxiliary cooling plate having a ring structure and connected to the cooling plate.

According to some embodiments, the heat dissipation module may include: a cooling plate having a ring structure and having at least one communication hole aligned with one end of the cooling passage; and a guide portion adjacent to the communication hole and protruding outward from one surface of the cooling plate.

According to some embodiments, a driving wheel that can perform effective cooling, and a transport apparatus including the same can be provided.

### BRIEF DESCRIPTION OF THE DRAWINGS

FIG. 1 shows a transport apparatus according to some embodiments.

FIG. 2 shows the driving wheel of FIG. 1.

FIG. 3 shows a state where a heat dissipation module has been removed from the driving wheel of FIG. 2.

FIG. 4 shows a wheel housing of FIG. 2.

FIG. 5 is a drawing projecting a cooling passage and a fastening groove located in a section of the wheel housing on a plane.

FIG. 6 and FIG. 7 are drawings showing the flow of air formed around the wheel housing and in the cooling passage when the transport apparatus is driving.

FIG. 8 shows the heat dissipation module of FIG. 2.

FIG. 9 and FIG. 10 are enlarged views of some areas of the heat dissipation module.

FIG. 11 shows a heat dissipation module according to some embodiments.

FIG. 12 is an enlarged view of some area of the heat dissipation module of FIG. 11.

FIG. 13 shows a driving wheel according to some embodiments.

### DETAILED DESCRIPTION

Hereinafter, with reference to the accompanying drawing, various embodiments of the present disclosure are described in detail such that a person of ordinary skill in the art to which the present disclosure belongs can easily practice the invention. The present disclosure may be implemented in many different forms and is not limited to the embodiments described herein.

The drawings and description are to be regarded as illustrative in nature and not restrictive, and like reference numerals designate like elements throughout the specification.

In the drawings, size and thickness of each element are arbitrarily illustrated for convenience of description, and the present disclosure is not necessarily limited to as illustrated in the drawings. In the drawings, the thickness of layers, films, panels, regions, etc., are exaggerated for clarity. In addition, in the drawings, for better understanding and ease of description, the thicknesses of some layers and regions are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to be positioned above or below the target element, and will not necessarily be understood to be positioned “at an upper side” based on an opposite to gravity direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

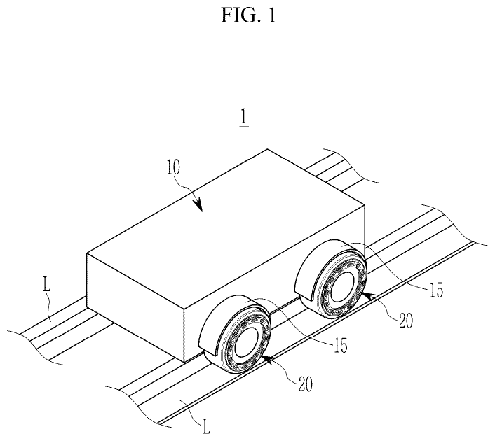

FIG. 1 shows a transport apparatus 1 according to some embodiments.

Referring to FIG. 1, transport apparatus 1 according to some embodiments may include a body 10 and a driving wheel 20.

The transport apparatus 1 may be used for transporting goods. The transport apparatus 1 may be used to transport goods in a clean room where equipment for producing a display panel, a semiconductor, and the like is positioned. The goods transported by the transport apparatus 1 may be goods used in the production process of the display panel, the semiconductor, and the like, a display panel undergoing the production process, a wafer undergoing the production process, and the like. For example, the transport apparatus 1 may be located on a rail L installed inside a clean room and provided to move along the rail L.

The body 10 may have a volume (e.g., a set or predetermined volume). In addition, the body 10 may have a structure for loading the goods to be transported. For example, the body 10 may have a loading space on one side for loading goods. In addition, the body 10 may have at least some areas that have liftable structures. In addition, the body 10 may include an accessory part used for loading or unloading the goods. In addition, the body 10 may include a configuration that provides power for driving. The configuration that provides power for driving may be a motor and the like.

The driving wheel 20 is connected to the body 10. The driving wheel 20 may be located on opposite ends in a width direction of the body 10. For example, two driving wheels 20 are located on both sides of the body 10 in the width direction such that four driving wheels 20 may be connected to the body 10. A cover 15 may be located in an upper region of the driving wheel 20. The cover 15 may be connected to the body 10. The cover 15 may be located at a distance (e.g., a set or predetermined distance) from the driving wheel 20. The cover 15 may block the upward flow of air around the driving wheel 20. Accordingly, the cover 15 may prevent or reduce instances of particles and the like diffusing due to the rising air current generated around the driving wheel 20 during the driving of the transport apparatus 1.

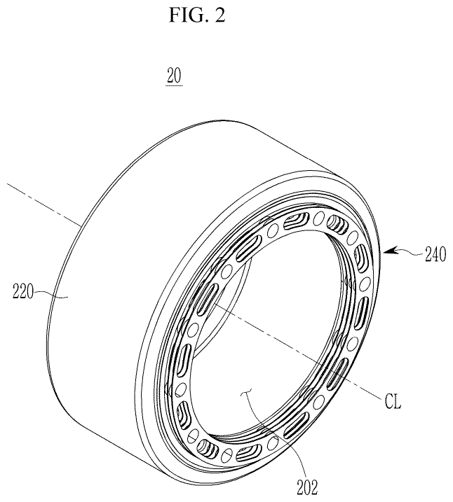

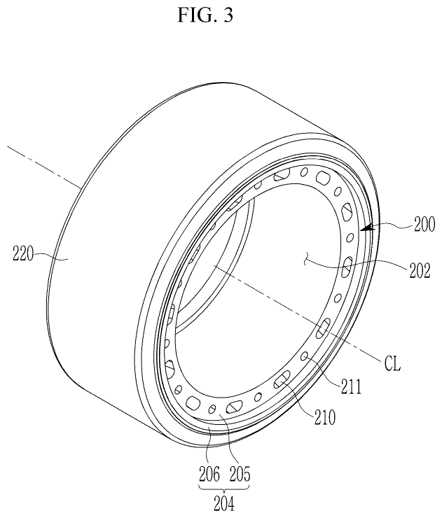

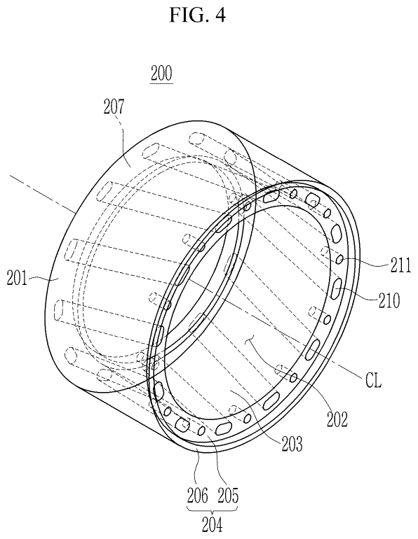

FIG. 2 shows the driving wheel 20 of FIG. 1, FIG. 3 shows a removal state of a heat dissipation module 240 in the driving wheel 20 of FIG. 2, and FIG. 4 shows a wheel housing 200 of FIG. 2.

Referring to FIG. 2 to FIG. 4, the driving wheel 20 according to some embodiments may include a wheel housing 200, a tire 220, and a heat dissipation module 240.

The wheel housing 200 may provide a frame of the driving wheel 20. The wheel housing 200 may be rotatably connected to the body 10 around a central axis CL. For example, the central axis CL may be oriented in a width direction of the body 10.

The wheel housing 200 may have a length (e.g., a set or predetermined length) along the central axis CL direction. An exterior surface 201 of the wheel housing 200 may be provided in a circular shape along a circumferential direction centered around the central axis CL. Accordingly, the wheel housing 200 may have a cylinder structure having a length (e.g., a set or predetermined length) along the central axis CL direction. The wheel housing 200 may have a penetration hole 202 positioned along the central axis CL direction in an inner central region. Accordingly, the wheel housing 200 may have a pipe structure having a length (e.g., a set or predetermined length) in the central axis CL direction and a thickness (e.g., a set or predetermined thickness) between the exterior surface 201 and an inner surface 203 in the radial direction with respect to the central axis CL. The wheel housing 200 may be rotatably connected to the body 10 around the central axis CL through the penetration hole 202. The inner surface 203 of the wheel housing 200 facing the penetration hole 202 may be provided in a circular shape along a circumferential direction centered on the central axis CL.

The wheel housing 200 includes a first side 204 and a second side 207, which are located at each end along the central axis CL direction. It may be understood that the first side 204 and the second side 207 are located between the exterior surface 201 and the inner surface 203. When the wheel housing 200 is connected to the body 10, the first side 204 may be arranged in the opposite direction of the body 10 along the central axis CL direction. When the wheel housing 200 is connected to the body 10, the second side 207 may be positioned in a direction toward the body 10 along the central axis CL direction.

At least one cooling passage 210 may be located in the wheel housing 200. The cooling passage 210 may be arranged to pass between the first side 204 and the second side 207. Accordingly, one end of the cooling passage 210 may be connected to the outside on the first side 204, and the other end of the cooling passage 210 may be connected to the outside on the second side 207. The cooling passage 210 may be provided in plurality and spaced apart from each other along a circumferential direction centered around the central axis CL. In this case, distances between two cooling passages 210 adjacent to each other along the circumferential direction centered on the central axis CL may correspond to each other. In addition, distance between two cooling passages 210 adjacent to each other along the circumferential direction centered on the central axis CL may be different for each section. The cross-section of the cooling passage 210 along a direction perpendicular to the central axis CL may have a circular shape, an elliptical shape, a polygonal shape, and the like. In addition, the cooling passage 210 may have a structure in which both ends of the 1 circumferential direction centered on the central axis CL are rounded. The wheel housing 200 may be effectively cooled by air flowing through the cooling passage 210.

At least one fastening groove 211 may be located in the wheel housing 200. The fastening groove 211 is provided to extend to a depth (e.g., a set or predetermined depth) in a direction from the first side 204 to the second side 207. The fastening grooves 211 may be provided in multiple numbers spaced apart from each other along a circumferential direction centered around the central axis CL. For example, at least one fastening groove 211 may be located between two cooling passages 210 adjacent to each other along the circumferential direction centered on the central axis CL. In addition, at least one fastening groove 211 may be located in some of the sections between two cooling passages 210 adjacent to each other along the circumferential direction centered on the central axis CL, and there may be no fastening groove 211 in the remaining sections. FIG. 3 and FIG. 4 illustrate a case in which one fastening groove 211 is positioned between two cooling passages 210 adjacent to each other along the circumferential direction centered on the central axis CL.

The first side 204 may include a fastening portion 205 and a raised portion 206. The fastening portion 205 may be located in an inner region of the first side 204 along the radial direction centered on the central axis CL. The raised portion 206 may be located in an outer region of the first side 204 along the radial direction centered on the central axis CL. The raised portion 206 may be arranged to protrude by an accommodation depth dh from the fastening portion 205 in the opposite direction of the second side 207 along the central axis CL direction. In addition, it may be understood that the fastening portion 205 may be sunken by the accommodation depth dh in a direction toward the second side 207 more than the raised portion 206. That is, the raised portion 206 may be a rib structure that is protruded by the accommodation depth dh in the opposite direction of the second side 207 from the outer circumference of the fastening portion 205. A width of the fastening portion 205 along the radial direction centered on the central axis CL may be provided to be larger than a width of the raised portion 206. One end of the cooling passage 210, that is, the fastening groove 211 may be located on the fastening portion 205.

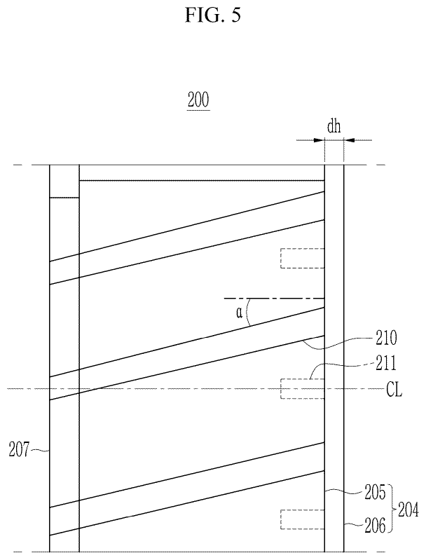

FIG. 5 is a drawing projecting the cooling passage 210 and the fastening groove 211 located in a section of the wheel housing 200 on a plane.

Referring to FIG. 5, a length direction of the cooling passage 210 may be inclined at an angle (e.g., a set or predetermined angle) a with respect to a direction parallel with the central axis CL. In this case, the length direction of the cooling passage 210 may be a direction from one end of the cooling passage 210 located on the first side 204 to the other end of the cooling passage 210 located on the second side 207. The size of the angle α at which the length direction of cooling passage 210 is inclined with respect to the direction parallel to the central axis CL may acute. In addition, angles α of the plurality of cooling passages 210 inclined with respect to the direction parallel to the central axis CL may correspond to each other.

The length direction of the fastening groove 211 may be directed in a direction parallel to the central axis CL. An inner end of the fastening groove 211 is spaced apart from the cooling passage 210, and thus the fastening groove 211 and the cooling passage 210 may be provided separately from each other.

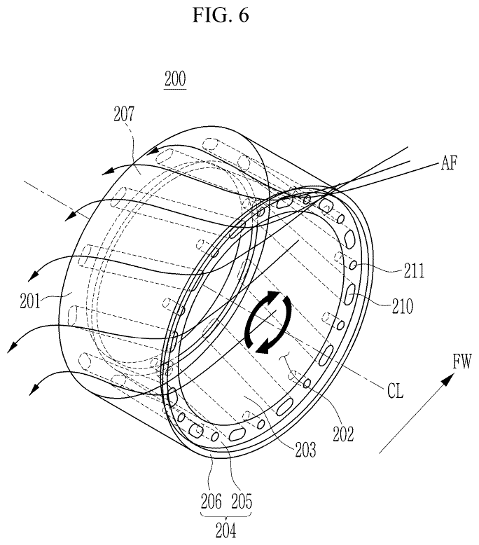

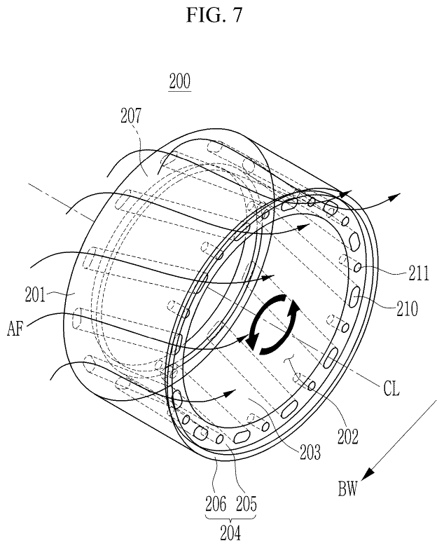

FIG. 6 and FIG. 7 are drawings showing the flow of air formed around the wheel housing 200 and in the cooling passage 210 when the transport apparatus 1 is driving.

Referring to FIG. 6 and FIG. 7, when the transport apparatus 1 is driving, an air flow is formed around the driving wheel 20 and inside the cooling passage 210. That is, as shown in FIG. 6, when the driving wheel 20 rotates in one direction, an airflow may be formed in the cooling passage 210 from the first side 204 toward the second side 207. In this case, the direction of air flow around the wheel housing 200 in a region adjacent to the first side 204 may be oriented towards an inclined direction of the cooling passage 210 as it progresses from the first side 204 to the second side 207. Accordingly, air in the region adjacent to the first side 204 may effectively enter the cooling passage 210.

In addition, as shown in FIG. 7, when the driving wheel 20 rotates in a different direction, an air flow may be formed in the cooling passage 210 in a direction from the second side 207 toward the first side 204. In this case, the direction of air flow around the wheel housing 200 in a region adjacent to the second side 207 may be oriented towards an inclined direction as the cooling passage 210 progresses from the second side 207 to the first side 204. Accordingly, air in the region adjacent to the second side 207 may effectively enter the cooling passage 210.

For example, FIG. 6 may show the rotation direction when the driving wheel 20 is in normal rotation, and the air flow direction formed around the driving wheel 20. In addition, FIG. 7 may show the rotating direction when the driving wheel 20 is in reverse rotation, and the air flow direction formed around the driving wheel 20. The rotating direction when the driving wheel 20 is in normal rotation may be the rotating direction when the transport apparatus 1 moves forward FW. In addition, the rotating direction when the driving wheel 20 is in reverse rotation may be the rotating direction when the transport apparatus 1 moves backward BW.

The transport apparatus 1 may have a longer forward (FW) operation time than backward (BW) operation time during its usage time. In addition, due to interference between the body 10 and the air, the cooling efficiency due to the air flow may be higher when the flow direction of the air inside the cooling passage 210 is from the first side 204 to the second side 207. Accordingly, a length direction of the cooling passage 210 may be inclined in the opposite direction of the rotating direction of the wheel housing 200 (i.e., opposite to a forward rotation direction) as it progresses from the first side 204 to the second side 207 when the transport apparatus 1 moves forward (FW). In other words, the length direction of the cooling passage 210 may be inclined in the rotating direction of the wheel housing 200 (i.e., a reverse rotating direction) when the transport apparatus 1 moves backward (BW), as it progresses from the first side 204 to the second side 207.

The tire 220 may be located at the outer circumference of the wheel housing 200. A material of the tire 220 may include synthetic rubber and the like. For example, the material of tire 220 may include polyurethane and the like.

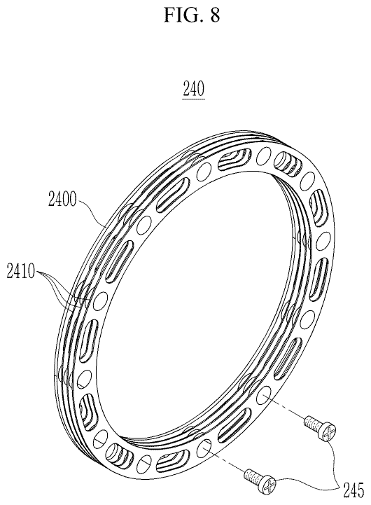

The heat dissipation module 240 is connected to the wheel housing 200 to increase a contact area with the air. The heat dissipation module 240 may be fixed to the first side 204 of the wheel housing 200. For example, the heat dissipation module 240 may be fixed to the first side 204 of the wheel housing 200 by a fastening member (245 of FIG. 8), which may be a bolt, a retaining pin, or the like.

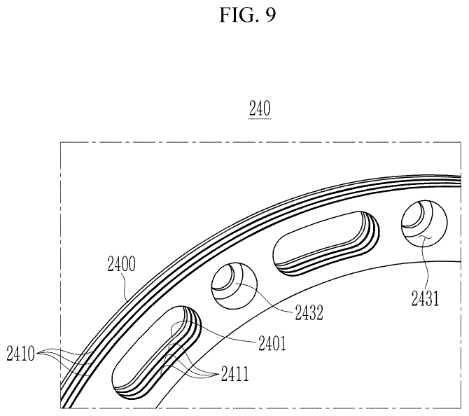

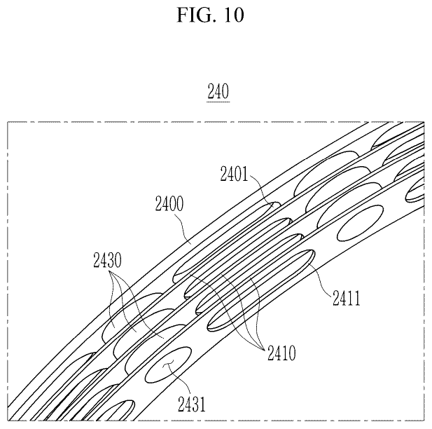

FIG. 8 shows the heat dissipation module 240 of FIG. 2, and FIG. 9 and FIG. 10 are enlarged views of some areas of the heat dissipation module 240.

Referring to FIG. 8 to FIG. 10, the heat dissipation module 240 according to some embodiments may include a cooling plate 2400 and an auxiliary cooling plate 2410.

The cooling plate 2400 may be connected to the first side 204 of the wheel housing 200. For example, the cooling plate 2400 may be fastened to the first side 204 of the wheel housing 200 by the fastening member 245. The cooling plate 2400 may be provided in a ring structure. The cooling plate 2400 may be provided as a circular ring structure having a width (e.g., a set or predetermined width) in the radial direction. The cooling plate 2400 may have a shape corresponding to the first side 204. The cooling plate 2400 may have a shape corresponding to the fastening portion 205 of the first side 204. That is, the width of the cooling plate 2400 in the radial direction may correspond to the width of the fastening portion 205 in the radial direction. In addition, an outer circumference of the cooling plate 2400 may correspond to an outer circumference of the fastening portion 205. Accordingly, the cooling plate 2400 may be coupled to the wheel housing 200 as a structure positioned at the fastening portion 205. A thickness of cooling plate 2400 may correspond to the accommodation depth dh.

At least one communication hole 2401 may be located in the cooling plate 2400. The communication hole 2401 may be arranged to penetrate both sides of the cooling plate 2400 in a direction parallel to the central axis CL. The communication hole 2401 may be provided in plurality and spaced apart from each other along the circumferential direction centered on the central axis CL. In this case, distances between two communication holes 2401 adjacent to each other along the circumferential direction centered on the central axis CL may correspond to each other. In addition, distance between two communication holes 2401 adjacent to each other along the circumferential direction centered on the central axis CL may be different for each section. The communication hole 2401 may be arranged to correspond to one end of the cooling passage 210 positioned on the first side 204. The communication hole 2401 may have a circular shape, an elliptical shape, a polygonal shape, and the like. In addition, the communication hole 2401 may have a rounded structure at both ends in the circumferential direction centered on the central axis CL. The shape of communication hole 2401 may correspond to the shape of the cross-section of the cooling passage 210. When the heat dissipation module 240 is connected to the wheel housing 200, the communication hole 2401 may be aligned with one end of the cooling passage 210 positioned on the first side 204.

The cooling plate 2400 may be connected to at least one auxiliary cooling plate 2410. The auxiliary cooling plate 2410 may be provided in a ring structure. The auxiliary cooling plate 2410 may be provided as a circular ring structure having a width (e.g., a set or predetermined width) in the radial direction. The auxiliary cooling plate 2410 may have a shape corresponding to the cooling plate 2400.

The auxiliary cooling plate 2410 may be connected to the cooling plate 2400 through the connection portion 2430. In addition, when two or more auxiliary cooling plates 2410 are provided, each auxiliary cooling plate 2410 may be connected to one another through the connection portion 2430. The connection portion 2430 may extend from the cooling plate 2400 toward the opposite direction of the wheel housing 200. For example, the connection portion 2430 may extend in a direction parallel to the length direction of the central axis CL. The surfaces of the cooling plate 2400 and the auxiliary cooling plate 2410 facing each other by the connection portion 2430 may be spaced apart by a distance (e.g., a set or predetermined distance) along the length direction of the central axis CL. The surfaces of the two auxiliary cooling plates 2410 facing each other by the connection portion 2430 may be spaced apart by a distance (e.g., a set or predetermined distance) along the length direction of the central axis CL.

The connection portion 2430 may be provided In plurality and spaced apart from each other along a circumferential direction centered around the central axis CL. For example, at least one connection portion 2430 may be located between two communication holes 2401 adjacent to each other along the circumferential direction centered on the central axis CL. In addition, along the circumferential direction centered on the central axis CL, at least one connection portion 2430 may be located in a portion of the section between two adjacent communication holes 2401, while the remining portion may be without a connection portion 2430. FIG. 8 to FIG. 10 illustrate a case in which one connection portion 2430 is positioned between two communication holes 2401 adjacent to each other along the circumferential direction centered on the central axis CL

At least one auxiliary communication hole 2411 may be located in the auxiliary cooling plate 2410. The auxiliary communication hole 2411 may be arranged to penetrate both sides of the auxiliary cooling plate 2410 in a direction parallel to the central axis CL. The auxiliary communication holes 2411 may be provided in plurality and spaced apart from each other along a circumferential direction centered around the central axis CL. In this case, distances between two auxiliary communication holes 2411 adjacent to each other along the circumferential direction centered on the central axis CL may correspond to each other. In addition, distance between two auxiliary communication holes 2411 adjacent to each other along the circumferential direction centered on the central axis CL may be different for each section. The auxiliary communication hole 2411 may be arranged corresponding to the communication hole 2401 positioned in the cooling plate 2400. Accordingly, the auxiliary communication hole 2411 may be aligned with the communication hole 2401 along a direction parallel to the central axis CL. The auxiliary communication hole 2411 may have a circular shape, an elliptical shape, a polygonal shape, and the like. In addition, the auxiliary communication hole 2411 may have a rounded structure at both ends in the circumferential direction centered on the central axis CL. The shape of the auxiliary communication hole 2411 may correspond to the shape of the communication hole 2401.

A fastening hole 2431 may be located in the cooling plate 2400. The fastening hole 2431 may be arranged to penetrate both sides of the cooling plate 2400 in a direction parallel to the central axis CL. The fastening hole 2431 may be provided in plurality and spaced apart from each other along a circumferential direction centered around the central axis CL. The fastening hole 2431 may be arranged to correspond to the fastening groove 211 positioned on the first side 204 of the wheel housing 200. Accordingly, the heat dissipation module 240 may be fixed to the wheel housing 200 as a structure in which the fastening hole 2431 and the fastening groove 211 are aligned and the fastening member 245 is inserted into the fastening hole 2431 and the fastening groove 211. For example, the fastening hole 2431 may be located in a region where the connection portion 2430 is positioned. Accordingly, the fastening hole 2431 may be arranged to penetrate an inner central region of the connection portion 2430, the cooling plate 2400, and the auxiliary cooling plate 2410 in a direction parallel to the central axis CL. An area of the fastening hole 2431 located on the cooling plate 2400 along a direction perpendicular to the central axis CL may be smaller than an area of the fastening hole 2431 located on the auxiliary cooling plate 2410 and the connection portion 2430. Accordingly, a fastening step 2432 protruding toward an inner center region may be located at the inner end of the fastening hole 2431 facing toward the wheel housing 200.

The transport apparatus 1 according to some embodiments allows the driving wheel 20 to be effectively cooled during use. Specifically, during use, a load is applied to the driving wheel 20 of the transport apparatus 1. Such load causes partial shrinkage and expansion of the tire 220. The tire 220 generates heat during the shrinkage and expansion process. Heat generated from the tire 220 causes changes in the physical properties of the tire 220, reducing the life span of the tire 220 and causing particles to be generated from the tire 220. On the other hand, the transport apparatus 1 according to some embodiments effectively cools the tire 220 and the wheel housing 200 through the cooling passage 210 positioned in the wheel housing 200. That is, the heat generated in tire 220 is transferred to the wheel housing 200, and the wheel housing 200 can be effectively cooled by air flowing through the cooling passage 210.

In addition, the transport apparatus 1 according to some embodiments can cool the wheel housing 200 more effectively by the heat dissipation module 240 connected to the wheel housing 200. In this case, the heat dissipation module 240 has a structure that increases a contact area with the air while effectively allowing air to flow between the cooling passage 210 of the wheel housing 200 and the outside, thereby achieving more effective cooling.

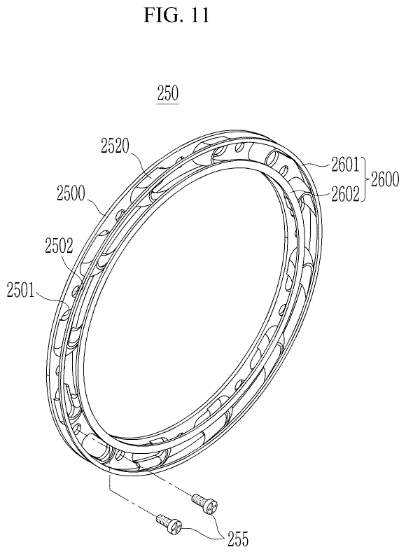

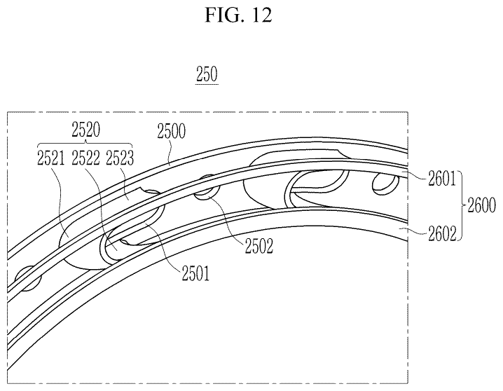

FIG. 11 shows a heat dissipation module 250 according to some embodiments, and FIG. 12 is an enlarged view of some area of the heat dissipation module 250 of FIG. 11.

Referring to FIG. 11 and FIG. 12, a heat dissipation module 250 according to some embodiments may include a cooling plate 2500 and an auxiliary cooling plate 2600.

The cooling plate 2500 may be connected to the first side 204 of the wheel housing 200. For example, the cooling plate 2500 may be fastened to the first side 204 of the wheel housing 200 by a fastening member 255, which may be a bolt, a retaining pin, or the like.

The cooling plate 2500 may be provided in a ring structure. The cooling plate 2500 may be provided as a circular ring structure having a width (e.g., a set or predetermined width) in the radial direction. The cooling plate 2500 may have a shape corresponding to the first side 204. The cooling plate 2500 may have a shape corresponding to the fastening portion 205 of the first side 204. That is, the width of the cooling plate 2500 in the radial direction may correspond to the width of the fastening portion 205 in the radial direction. In addition, an outer circumference of the cooling plate 2500 may correspond to an outer circumference of the fastening portion 205. Accordingly, the cooling plate 2500 may be coupled to the wheel housing 200 as a structure positioned at the fastening portion 205

A thickness of cooling plate 2500 may correspond to the accommodation depth dh.

At least one communication hole 2501 may be located in the cooling plate 2500. The communication hole 2501 may be arranged to penetrate both sides of the cooling plate 2500 in a direction parallel to the central axis CL

The communication hole 2501 may be provided in plurality and spaced apart from each other along the circumferential direction centered on the central axis CL. In this case, distances between two communication holes 2501 adjacent to each other along the circumferential direction centered on the central axis CL may correspond to each other. In addition, distance between two communication holes 2501 adjacent to each other along the circumferential direction centered on the central axis CL may be different for each section. The communication hole 2501 may be arranged to correspond to one end of the cooling passage 210 positioned on the first side 204. The communication hole 2501 may have a circular shape, an elliptical shape, a polygonal shape, and the like. In addition, the communication hole 2501 may have a rounded structure at both ends in the circumferential direction centered on the central axis CL. The shape of communication hole 2501 may correspond to the shape of the cross-section of the cooling passage 210. When the heat dissipation module 250 is connected to the wheel housing 200, the communication hole 2501 may be aligned with one end of the cooling passage 210.

A fastening hole 2502 may be disposed in the cooling plate 2500. The fastening hole 2502 may be arranged to penetrate both sides of the cooling plate 2500 in a direction parallel to the central axis CL. The fastening hole 2502 may be provided in plurality and spaced apart from each other along the circumferential direction centered on the central axis CL. The fastening hole 2502 may be arranged to correspond to the fastening groove 211 positioned on the first side 204 of the wheel housing 200. Accordingly, the heat dissipation module 250 may be fixed to the wheel housing 200 as a structure in which the fastening hole 2502 and the fastening groove 211 are aligned and the fastening member 255 is inserted into the fastening hole 2502 and the fastening groove 211.

A guide portion 2520 may be located in the cooling plate 2500. The guide portion 2520 is provided to protrude outward from one side of the cooling plate 2500. The guide portion 2520 is located adjacent to the communication hole 2501 such that the air flow generated when the driving wheel 20 rotates is directed toward the communication hole 2501 and the cooling passage 210. The guide portion 2520 may be located on one side of the communication hole 2501 with the circumferential direction centered on the central axis CL as a reference. The guide portion 2520 may be located adjacent to the communication hole 2501 on one side opposite to the rotating direction of the wheel housing 200 (i.e., opposite direction to a forward rotation direction) based on the circumferential direction centered on the central axis CL when the transport apparatus 1 moves forward. In other words, the guide portion 2520 may be located adjacent to the communication hole 2501 on one side of the rotating direction (i.e., reverse rotating direction) of the wheel housing 200 when the transport apparatus 1 moves backward, based on the circumferential direction centered on the central axis CL. Accordingly, the air flow generated when the driving wheel 20 rotates forward can be guided by an inner surface of the guide portion 2520 facing the communication hole 2501 and then directed toward the communication hole 2501.

The guide portion 2520 may include a main guide portion 2521, an inner guide portion 2522, and an outer guide portion 2523.

The main guide portion 2521 is arranged to surround one end of the communication hole 2501 along the circumferential direction centered on the central axis CL. The main guide portion 2521 may be arranged along a radial direction centered on the central axis CL over a distance (e.g., a set or predetermined distance). The main guide portion 2521 may be inclined to face towards the communication hole 2501 direction as it moves away from the cooling plate 2500.

The inner guide portion 2522 is connected to an inner end of the main guide portion 2521 in the radial direction. The inner guide portion 2522 is located adjacent to the inner end of the communication hole 2501 along the radial direction. The inner guide portion 2522 may have a length (e.g., a set or predetermined length) along the circumferential direction centered on the central axis CL. A length of the inner guide portion 2522 along the circumferential direction centered on the central axis CL may be provided to be smaller than a length of the communication hole 2501 along the circumferential direction centered on the central axis CL.

The outer guide portion 2523 is connected to an outer end of the main guide portion 2521 in the radial direction. The outer guide portion 2523 is located adjacent to an outer end of the communication hole 2501 along the radial direction. The outer guide portion 2523 may have a length (e.g., a set or predetermined length) along the circumferential direction centered on the central axis CL. A length of the outer guide portion 2523 along the circumferential direction centered on the central axis CL may be provided to be smaller than a length of the communication hole 2501 along the circumferential direction centered on the central axis CL. A length of the outer guide portion 2523 along the circumferential direction centered on the central axis CL may be provided to be longer than a length of the inner guide portion 2522 along the circumferential direction centered on the central axis CL.

The auxiliary cooling plate 2600 may be connected to the guide portion 2520. Accordingly, the guide portion 2520 may be a connection portion connecting the auxiliary cooling plate 2600 and the cooling plate 2500. The auxiliary cooling plate 2600 is located at a distance (e.g., a set or predetermined distance) from the cooling plate 2500 along a direction parallel to the central axis CL. The auxiliary cooling plate 2600 may include an outer auxiliary cooling plate 2601 and an inner auxiliary cooling plate 2602.

The outer auxiliary cooling plate 2601 may be provided in a ring structure. The outer auxiliary cooling plate 2601 may be provided as a circular ring structure having a width (e.g., a set or predetermined width) in the radial direction. A width of the outer auxiliary cooling plate 2601 along the radial direction may be provided to be smaller than a width of the cooling plate 2500 along the radial direction. The outer auxiliary cooling plate 2601 may be arranged to face an outer region of the cooling plate 2500 along the radial direction centered on the central axis CL. The outer auxiliary cooling plate 2601 may be connected to the outer guide portion 2523.

The inner auxiliary cooling plate 2602 may be provided in a ring structure. The inner auxiliary cooling plate 2602 may be provided as a circular ring structure having a width (e.g., a set or predetermined width) in the radial direction. A width of the inner auxiliary cooling plate 2602 along the radial direction may be provided to be smaller than a width of the cooling plate 2500 along the radial direction. The inner auxiliary cooling plate 2602 may be arranged to face an inner region of the cooling plate 2500 along the radial direction centered on the central axis CL. The inner auxiliary cooling plate 2602 may be connected to the inner guide portion 2522. The inner auxiliary cooling plate 2602 may be spaced apart from the outer auxiliary cooling plate 2601 along the radial direction.

According to some embodiments, a heat dissipation module 250 allows air to effectively enter a cooling passage 210 of a wheel housing 200 through a guide portion 2520.

In addition, the heat dissipation module 250 according to some embodiments can improve heat dissipation efficiency by increasing a contact area with air through an auxiliary cooling plate 2600.

In addition, according to some embodiments, the heat dissipation module 250 can prevent or reduce instances of the guide portion 2520 directly colliding with the worker or an external object through the auxiliary cooling plate 2600.

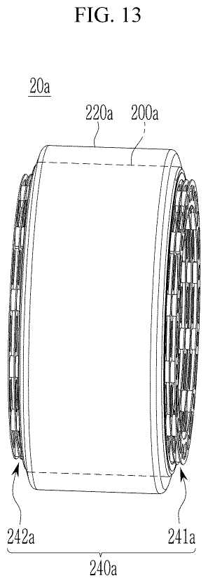

FIG. 13 shows a driving wheel 20a according to some embodiments.

Referring to FIG. 13, a driving wheel 20a according to some embodiments may include a wheel housing 200a, a tire 220a, and a heat dissipation module 240a.

The heat dissipation module 240a may include a first heat dissipation module 241a and a second heat dissipation module 242a.

The first heat dissipation module 241a may be connected to a first side of the wheel housing 200a. That is, the first heat dissipation module 241a may be arranged in the opposite direction of a body 10 with reference to the wheel housing 200a. The first heat dissipation module 241a is the same or similar to the heat dissipation module 240 described above with reference to FIG. 8 to FIG. 10 or the heat dissipation module 250 described above with reference to FIG. 11 and FIG. 12, and some repeated explanation for this may be omitted.

The second heat dissipation module 242a may be connected to a second side of the wheel housing 200a. That is, the second heat dissipation module 242a may be arranged to face the body 10. The second heat dissipation module 242a may be the same as or similar to the heat dissipation module 240a described above with reference to FIG. 8 to FIG. 10, and some repeated description thereof may be omitted. In addition, the second heat dissipation module 242a may have a structure similar to that of the heat dissipation module 250 described above with reference to FIGS. 11 and FIG. 12. In this case, the guide portion 2520 may be arranged adjacent to a communication hole 2501 on one side in the opposite direction of the rotating direction of the wheel housing 200a (i.e., the opposite direction of reverse rotation) when a transport apparatus 1 moves backward with the circumferential direction centered on the central axis CL as a reference. Accordingly, an air flow generated when the driving wheel 20a rotates in reverse can be guided by an inner surface of a guide portion 2520 facing the communication hole 2501 and then directed toward the communication hole 2501.

The wheel housings 200a and tire 220a are the same as or similar to the structures described above with reference to FIG. 1 to FIG. 7, and therefore some repeated descriptions may be omitted.

While aspects of some embodiments of the present disclosure have been described in connection with what is presently considered to be practical embodiments, it is to be understood that embodiments according to the present disclosure are not limited to the disclosed embodiments. On the contrary, it is intended to cover various modifications and equivalent arrangements included within the spirit and scope of the appended claims, and their equivalents.

What is claimed is:

1. A transport apparatus comprising:
a body; and
a driving wheel that is rotatably connected to the body around a central axis,
wherein the driving wheel comprises a wheel housing,
the wheel housing comprises a first side positioned opposite to the body along a central axis direction and a second side that faces the body, and
at least one cooling passage that penetrates between the first side and the second side is in the wheel housing.

2. The transport apparatus of claim 1, wherein:
the cooling passage is inclined with respect to a direction parallel to the central axis.

3. The transport apparatus of claim 2, wherein:
the cooling passage is inclined in a rotating direction of the wheel housing while receding from the first side towards the second side.

4. The transport apparatus of claim 1, wherein:
the cooling passage is provided in plurality and the plurality of cooling passages are arranged along a circumferential direction centered on the central axis.

5. The transport apparatus of claim 1, wherein:
the first side comprises:
a fastening portion that is in an inner region in a radial direction centered on the central axis; and
a raised portion in an outer region in the radial direction centered on the central axis, and
the raised portion is more protruding than the fastening portion in the opposite direction to the second side.

6. The transport apparatus of claim 5, wherein:
one end of the cooling passage is positioned in the fastening portion.

7. The transport apparatus of claim 1, wherein:
the driving wheel further comprises a heat dissipation module that is connected to the wheel housing and increases a contact area with air.

8. The transport apparatus of claim 7, wherein:
the heat dissipation module comprises:
a cooling plate having a ring structure; and
at least one auxiliary cooling plate having a ring structure and connected to the cooling plate.

9. The transport apparatus of claim 8, wherein:
at least one communication hole is on the cooling plate, the communication hole being aligned with one end of the cooling passage.

10. The transport apparatus of claim 9, wherein:
at least one auxiliary communication hole aligned with the communication hole is in the auxiliary cooling plate.

11. The transport apparatus of claim 9, further comprising a connection portion that connects the cooling plate and the auxiliary cooling plate.

12. The transport apparatus of claim 11, wherein:
the communication hole is provided in plurality, and
the connection portion is in a section between the plurality of communication holes.

13. The transport apparatus of claim 7, wherein:
the heat dissipation module comprises:
a cooling plate having a ring structure and having at least one communication hole aligned with one end of the cooling passage; and
a guide portion adjacent to the communication hole and protruding outward from one surface of the cooling plate.

14. The transport apparatus of claim 13, wherein:
the guide portion is adjacent to the communication hole on one side of the rotating direction of the wheel housing when reversing based on a circumferential direction.

15. The transport apparatus of claim 13, wherein:
the heat dissipation module further comprises an auxiliary cooling plate having a ring structure and connected to the guide portion.

16. A driving wheel comprising a wheel housing,
wherein the wheel housing comprises a first side and a second side respectively arranged at opposite ends along a central axis direction, and
a cooling passage that penetrates the first side and the second side is in the wheel housing.

17. The driving wheel of claim 16, wherein:
the cooling passage is inclined with respect to a direction parallel to a central axis.

18. The driving wheel of claim 16, further comprising a heat dissipation module connected to the first side of the wheel housing and increasing a contact area with air.

19. The driving wheel of claim 18, wherein:
the heat dissipation module comprises:
a cooling plate having a ring structure and having at least one communication hole aligned with one end of the cooling passage; and
at least one auxiliary cooling plate having a ring structure and connected to the cooling plate.

20. The driving wheel of claim 18, wherein:
the heat dissipation module comprises:
a cooling plate having a ring structure and having at least one communication hole aligned with one end of the cooling passage; and
a guide portion adjacent to the communication hole and protruding outward from one surface of the cooling plate.
